(19) United States
(12) Patent Application Publication
(10) Pub. No.: US 2006/0162769 A1
(43) Pub. Date: Jul. 27, 2006

(54) Low-temperature metal oxide coating

(76) Inventors: Emilio Palomares Gil, London (GB); John Noel Clifford, London (GB); Saif Ahmed Haque, London (GB); Thierry Lutz, London (GB); James Robert Durrant, London (GB)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 10/523,036

(22) PCT Filed: Aug. 4, 2003
(86) PCT No.: PCT/GB03/03397

§ 371 Date: Jan. 6, 2006

(30) Foreign Application Priority Data
Aug. 2, 2002 (GB) 0217990.1

(51) Int. Cl. H01L 31/00

(52) U.S. Cl. 136/263

(57) ABSTRACT

A low-temperature fabrication method for fabricating a conformal metal oxide coating on a substrate, the method comprising the steps of. coating a surface of a substrate with a non-hydrolysed precursor solution of one or more moisture-sensitive metal alkoxides in an organic solvent at a temperature of less than 150° C.; and rinsing the precursor solution coated on the surface of the substrate in water at a temperature of less than 150° C. to hydrolyse precursor solution at the surface of the substrate and thereby form a conformal metal oxide coating on the substrate.

The present invention relates to a fabrication method for the fabrication of metal oxide coatings at low temperature, in particular the conformal coating of surfaces, especially nanostructured surfaces and nanoparticles. In particular, the fabrication method of the present invention is suited to the conformal coating of reticulated and nanocrystalline films.

Several methods have been disclosed for the fabrication of metal oxide coatings.

One such method, and the most common method, is based on precursor pyrolysis. Typically, in this method, a colloidal suspension of semiconductor particles to be coated, for example, SnO₂, TiO₂ or ZnO particles, is prepared in a solution containing a precursor of the desired coating oxide, for example, aluminium acetate for an Al₂O₃ coating [1]. The coated particles are then subsequently subjected to a high-temperature heat treatment at a temperature of at least 150° C., and typically about 450° C., in order to provide for a complete reaction of the precursor to the oxide.

In another such method, a reticulated film is coated with a chloride precursor, for example, AlCl₃ or MgCl₂, diluted in an alcoholic solution [2]. The coated film is then subjected to a high-temperature heat treatment in order to provide for a complete reaction of the precursor to the oxide.

In a further such method, templates are utilized. The templates are typically surfactant micelles [3], such as cetyltrimethylammonium chloride. Following coating, the coated substrate is typically subjected to a heat treatment at a temperature of 100° C. for 48 hours in an enclosed reactor, and subsequently, in order to remove the templates, a high-temperature heat treatment at a temperature of 450° C. for 2 hours.

These methods each require a high-temperature heat treatment, and thus, in particular, are not suited to the coating of temperature-sensitive substrates. The requirement for a high-temperature heat treatment is a significant limitation to the applicability of these methods, in limiting the techniques to temperature-stable substrates, such as glass, and the coatings to ones which comprise temperature-stable components.

A low-temperature fabrication method has been developed for the fabrication of amorphous metal oxides on substrates, as embodied a gold-coated quartz crystal microbalance (QCM) [4]. In this method, a precursor solution is prepared of a metal alkoxide precursor in an organic solvent, for example, toluene and ethanol. The metal alkoxide in the precursor solution is partially hydrolysed, resulting in a sol. The substrate is then coated by dipping the substrate in the sol, and subsequently rinsed with water. In this method, the formation of a sol is required prior to coating. As the sol comprises partially-polymerised metal oxide suspended in solution, which is an optical scattering solution, the method is particularly unsuited to the conformal coating of reticulated and nanocrystalline films.

It is an aim of the present invention to provide a fabrication method for the fabrication of metal oxide coatings at low-temperature, in particular the conformal coating of reticulated films, nanocrystalline films and nanoparticles.

In one aspect the present invention provides a low-temperature fabrication method for fabricating a conformal metal oxide coating on a substrate, the method comprising the steps of: coating a surface of a substrate with a non-hydrolysed precursor solution of one or more moisture-sensitive metal alkoxides in an organic solvent at a temperature of less than 150° C.; and rinsing the precursor solution coated on the surface of the substrate in water at a temperature of less than 150° C. to hydrolyse precursor solution at the surface of the substrate and thereby form a conformal metal oxide coating on the substrate.

Preferably, the one or more moisture-sensitive metal alkoxides comprise M(OR)_{z}, where M is any metal, and OR is an alkoxide group.

More preferably, the metal is a metal selected from the group consisting of Al, Ce, Mg, Nb, Si, Sn, Ti, V, Zn and Zr.

Preferably, the step of coating a surface of a substrate is performed at room temperature.

In one embodiment the step of coating a surface of a substrate is performed by dipping the surface of the substrate in the precursor solution.

Preferably, the surface of the substrate is dipped in the precursor solution for a period of from about 1 minute to about 1 hour.

In another embodiment the step of coating a surface of a substrate is performed by spraying the surface of the substrate with the precursor solution.

In a further embodiment the step of coating a surface of a substrate is performed by spin-coating the surface of the substrate with the precursor solution.

Preferably, the precursor solution has a concentration of less than about 200 mM.

More preferably, the precursor solution has a concentration in the range of from about 1 mM to about 100 mM.

Yet more preferably, the precursor solution has a concentration in the range of from about 5 mM to about 20 mM.

Preferably, the step of rinsing the precursor solution coated on the surface of the substrate is performed at room temperature.

Preferably, the step of rinsing the precursor solution coated on the surface of the substrate is performed by dipping the coated surface of the substrate in water.

Preferably, the method further comprises the step of: drying the rinsed surface of the substrate at a temperature of less than 150° C.

More preferably, the step of drying the rinsed surface of the substrate is performed at room temperature.

In a preferred embodiment the step of drying the rinsed surface of the substrate is performed by directing a gas flow thereover.

In one embodiment the surface of the substrate is a flat surface.

In another embodiment the surface of the substrate comprises a structured surface.

In one embodiment the surface of the substrate comprises a nanoporous surface.

In another embodiment the structured surface comprises a reticulated surface.

In one embodiment the substrate includes a temperature-sensitive element.

In one embodiment the temperature-sensitive element is selected from the group consisting of a plastic and a polymer.

In another embodiment the temperature-sensitive element comprises temperature-sensitive molecules.

In one embodiment the molecules are selected from the group consisting of inorganic, organic and organometallic molecules.

In another embodiment the molecules are polymers.

In a further embodiment the molecules are biomolecules.

In a yet further embodiment the molecules are biological macromolecules.

Preferably, the biological macromolecules are selected from the group consisting of proteins and nucleic acids.

In one embodiment the molecules are at the surface of the substrate.

In one embodiment the coating extends over regions of the surface of the substrate not encompassed by the molecules.

In another embodiment the coating encapsulates the molecules.

In a yet further embodiment the substrate comprises particles.

In one embodiment the particles comprise dry particles.

In another embodiment the particles are suspended in solution.

Preferably, the particles comprise nanoparticles.

Preferably, the metal oxide coating has a thickness of from about 0.2 to about 10 nm.

More preferably, the metal oxide coating has a thickness of from about 0.2 to about 1 nm.

In another aspect the present invention provides a low-temperature fabrication method for fabricating a metal oxide coating on a substrate, the method comprising the steps of: coating a surface of a substrate with a non-hydrolysed precursor solution of one or more moisture-sensitive metal alkoxides in an organic solvent at a temperature of less than 150° C.; and hydrolysing precursor solution at the surface of the substrate to form a metal oxide coating at a temperature of less than 150° C.

Preferably, the metal oxide coating is a conformal coating.

Preferably, the precursor solution has a concentration of less than about 200 mM.

More preferably, the precursor solution has a concentration in the range of from about 1 mM to about 100 mM.

Yet more preferably, the precursor solution has a concentration in the range of from about 5 mM to about 20 mM.

Preferably, the step of hydrolysing the precursor solution coated on the surface of the substrate is performed in water.

Preferably, the step of hydrolysing the precursor solution coated on the surface of the substrate is performed at room temperature.

Preferably, the step of hydrolysing the precursor solution coated on the surface of the substrate is performed by rinsing the coated surface of the substrate.

Preferably, the method further comprises the step of: drying the hydrolysed surface of the substrate at a temperature of less than 150° C.

More preferably, the step of drying the hydrolysed surface of the substrate is performed at room temperature.

In one embodiment the step of drying the hydrolysed surface of the substrate is performed by directing a gas flow thereover.

Preferably, the metal oxide coating has a thickness of from about 0.2 nm to about 10 nm.

More preferably, the metal oxide coating has a thickness of from about 0.2 nm to about 1 nm.

The present invention also extends to a device incorporating a substrate having a metal oxide coating as fabricated by the above-described methods.

Preferably, the device is one of an electronic or optoelectronic device.

More preferably, the device is a photovoltaic device.

Yet more preferably, the device is a dye sensitized solar cell.

In a further aspect the present invention provides a dye sensitized solar cell device, comprising a nanocomposite film sandwiched between a pair of electrodes, wherein the nanocomposite film comprises a mesoporous, nanocrystalline film conformally coated with a first coating of a metal oxide and a second coating of a sensitizing dye, and a redox-active electrolyte interpenetrated into the pores of the nanocrystalline film.

Preferably, the metal oxide coating has a thickness of from about 0.2 nm to about 10 nm.

More preferably, the metal oxide coating has a thickness of from about 0.2 nm to about 1 nm.

In one embodiment the metal oxide comprises Al₂O₃.

In one embodiment the nanocomposite film comprises TiO₂.

In one embodiment the redox-active electrolyte comprises a polymer electrolyte.

In a yet further aspect the present invention provides a non-hydrolysed precursor solution of one or more moisture-sensitive metal alkoxides in an organic solvent.

Preferably, the one or more moisture-sensitive metal alkoxides comprise M(OR)_{z}, where M is any metal, and OR is an alkoxide group.

More preferably, the metal is a metal selected from the group consisting of Al, Ce, Mg, Nb, Si, Sn, Ti, V, Zn and Zr.

Preferably, the precursor solution has a concentration of less than about 200 mM.

More preferably, the precursor solution has a concentration in the range of from about 1 mM to about 100 mM.

Yet more preferably, the precursor solution has a concentration in the range of from about 5 mM to about 20 mM.

In a still further aspect the present invention provides a method of preparing a non-hydrolysed precursor solution of one or more moisture-sensitive metal alkoxides in an organic solvent, the method comprising the step of mixing one or more moisture-sensitive metal alkoxides in an organic solvent in a controlled environment containing less than about 10 ppm water.

Preferably, the method is performed at room temperature.

Preferably, the controlled environment is an inert atmosphere.

Preferably, the one or more moisture-sensitive metal alkoxides comprise M(OR)_{z}, where M is any metal, and OR is an alkoxide group.

More preferably, the metal is a metal selected from the group consisting of Al, Ce, Mg, Nb, Si, Sn, Ti, V, Zn and Zr.

Preferably, the precursor solution has a concentration of less than about 200 mM.

More preferably, the precursor solution has a concentration in the range of from about 1 mM to about 100 mM.

Yet more preferably, the precursor solution has a concentration in the range of from about 5 mM to about 20 mM.

The low-temperature coating method of the present invention allows for the fabrication of coatings having a thickness of less than one nanometer to hundreds of nanometers, with repeated deposition allowing for the fabrication of coatings of increased thickness.

In the context of the present invention, low temperature relates to temperatures of less than 150° C., especially less than 100° C., and in particular encompassing the fabrication of coatings at room temperature.

Low-temperature processing is attractive in reducing cost and environmental waste, and, moreover, allows for the coating of temperature-sensitive substrates, in particular organic substrates, such as polymers and plastics.

The present invention finds particular application in the conformal coating of highly-structured inorganic films. Such films are utilized in a wide range of photochemical, photocatalytic, optoelectronic and electronic devices. Particular examples are the use of mesoporous, nanocrystalline metal oxide films for optoelectronic devices, such as photovoltaic or photoelectrochemical solar cells, light-emitting devices, and photocatalytic devices for the decomposition of pollutants or the photocatalytic scavenging of oxygen from closed environments.

The conformal coating of structured inorganic films with a thin layer, typically from about 0.2 nm to about 10 nm, of a metal oxide is particularly attractive in enabling control of the surface properties of such films. For example, the fabrication of conformal insulating layers on nanocrystalline metal oxide films provides for the retardation of interfacial recombination processes. Such barrier layers could comprise low-electron affinity metal oxides, such as Al₂O₃, MgO, SiO₂ or ZrO₂. These coatings would be particularly attractive for device applications including photovoltaic cells and photochromic films.

Another application is the coating of metal oxide particles with a barrier layer to prevent photocatalytic, photochemical or other activity. Such passivated particles, for example, TiO₂ particles coated with Al₂O₃, are widely used as whiteners or light scatterers in the pigment, dye and cosmetic industries.

A further application is the coating of flat substrates, including temperature-sensitive substrates, such as plastics, for example, in order to provide an electrically-insulating barrier layer. Such substrates include ITO or F:SnO₂ coated plastic or glass.

A yet further application is the coating of metal oxide films, in particular reticulated and nanocrystalline films, having temperature-sensitive molecules pre-absorbed thereon. Such molecules include inorganic, organic and organometallic molecules, polymers, biomolecules and biological macromolecules, such as proteins and nucleic acids. In one embodiment the coating can extend over regions of the surface of the substrate which are not encompassed by the temperature-sensitive molecules. In another embodiment the coating can encapsulate the temperature-sensitive molecules.

Preferred embodiments of the present invention will now be described hereinbelow by way of example only with reference to the accompanying drawings, in which:

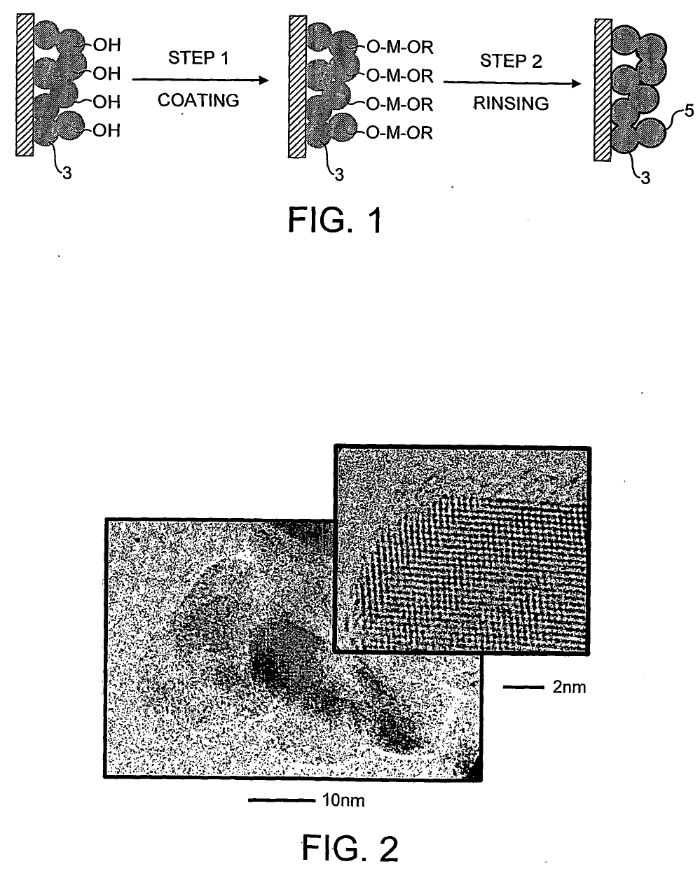

FIG. 1 schematically represents the fabrication steps in fabricating a conformal metal oxide coating on a substrate in accordance with a preferred embodiment of the present invention;

FIG. 2 illustrates high-resolution TEM images of crystalline TiO₂ nanoparticles coated with an Al₂O₃ coating as fabricated in accordance with the method of FIG. 1;

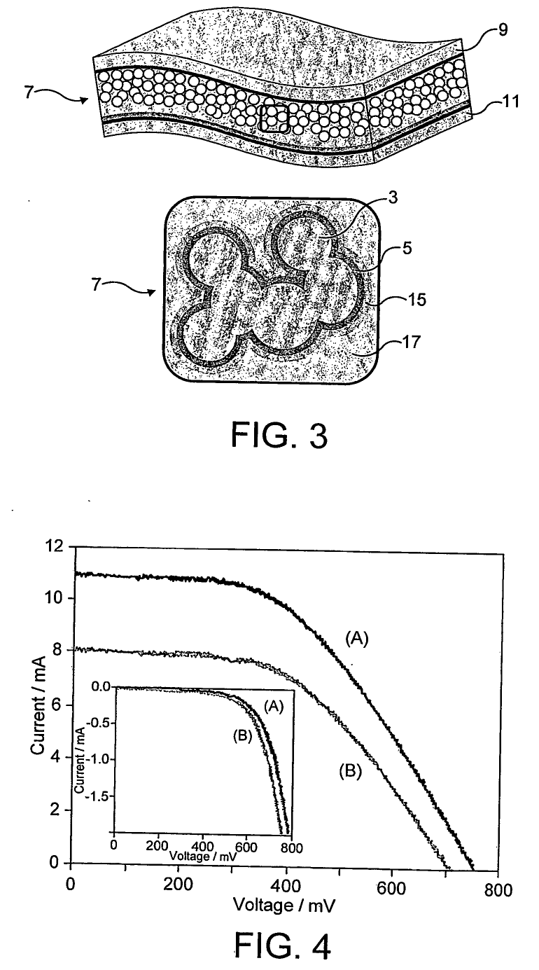

FIG. 3 schematically represents a dye sensitized nanocrystalline solar cell (DSSC) as fabricated in accordance with a preferred embodiment of the present invention;

FIG. 4 illustrates the current-voltage characteristics of dye-sensitized, nanocrystalline sandwich solar cell structures incorporating a TiO₂ film having an Al₂O₃ conformal coating (plot A) and an uncoated TiO₂ film (plot B) as fabricated in accordance with Example I;

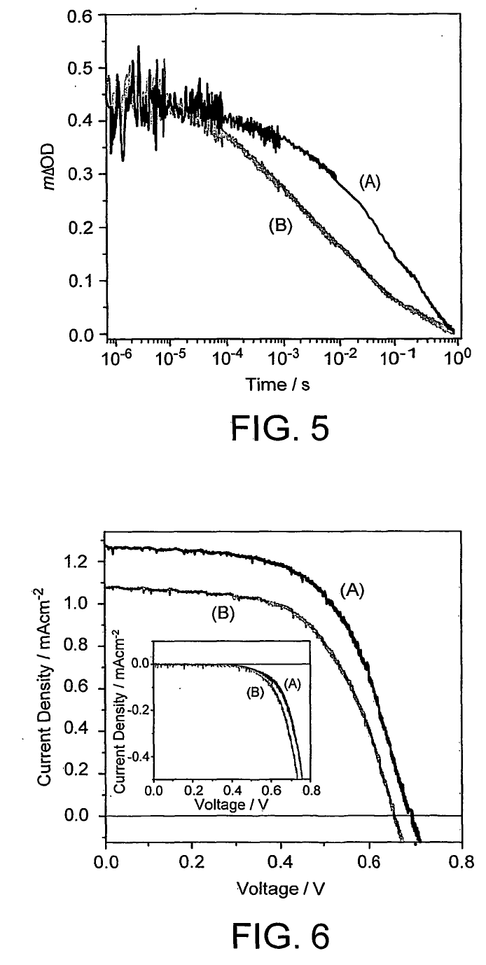

FIG. 5 illustrates the photoinduced absorption of the RuL₂(NCS)₂ cation following optical excitation of the dye adsorbed on an Al₂O₃ coated TiO₂ film (plot A) and an uncoated TiO₂ film (plot B) as fabricated in accordance with Example II; and

FIG. 6 illustrates the current-voltage characteristics of dye-sensitized, nanocrystalline sandwich solar cell structures incorporating a TiO₂ film having an Al₂O₃ conformal coating (plot A) and an uncoated TiO₂ film (plot B) as fabricated in accordance with Example II.

A method of coating a substrate 3, in this embodiment a mesoporous, nanocrystalline film, with a metal oxide coating 5, in this embodiment a conformal coating, will now be described hereinbelow with reference to FIG. 1.

A stable, non-hydrolysed precursor solution, as a coating solution, is first prepared of one or more moisture-sensitive metal alkoxides in an organic solvent.

The moisture-sensitive alkoxides can be expressed generally as M(OR)_{z}, where M is any metal, OR is an alkoxide group and z is the valence or oxidation state of the metal. In preferred embodiments the metal is a metal selected from the group consisting of Al, Ce, Mg, Nb, Si, Sn, Ti, V, Zn and Zr.

The one or more metal alkoxide precursors are diluted in an organic solvent at room temperature, typically at about 25° C., to provide a precursor solution. Examples of such precursor solutions include a solution of aluminum tri-sec-butoxide in dry iso-propanol, a solution of silicon methoxide in dry methanol, and a solution of zirconium iso-butoxide in dry iso-propanol. The precursor solution preferably has a concentration of less than about 200 mM and more preferably greater than about 1 mM, more preferably less than about 150 mM, yet more preferably in the range of from about 1 mM to about 100 mM, still more preferably in the range of from about 5 mM to about 20 mM, yet still more preferably in the range of from about 5 mM to about 15 mM, and yet still further more preferably in the range of from about 5 mM to about 7.5 mM.

In a preferred embodiment the precursor solution is prepared in an inert atmosphere, here nitrogen, and under a strictly-controlled water presence, here less than about 10 ppm, in order to avoid partial sol-gel hydrolysis. In this embodiment the controlled environment for the precursor solution is provided in a glove box.

The present inventors have recognized that, with suitable solvent and precursor concentrations, the precursor solution is rendered insensitive to the atmosphere. The precursor solution is stable for several months under normal atmosphere; the solution remaining clear without any visible precursor hydrolysis.

Referring to FIG. 1 (step 1), the substrate 3 is coated with the precursor solution, in this embodiment by dipping the substrate 3 in the precursor solution for a period of time, in a preferred embodiment from about 10 minutes to about 1 hour at room temperature under aerobic conditions. In alternative embodiments the substrate 3 could be coated using alternative coating techniques, such as spraying or spin-coating.

On coating the substrate 3 with the precursor solution, the non-hydrolysed metal alkoxides of the precursor solution start reacting with the hydroxylated surface of the substrate 3, leading to the formation of a primary shell, in this embodiment conformally coating the nanoparticles of the substrate 3.

Referring to FIG. 1 (step 2), following coating of the substrate 3, the coated surface of the substrate 3 is rinsed with water, in this embodiment by dipping in a water bath.

Rinsing the surface of the substrate 3 with water drives the hydrolysis of the metal alkoxides of the primary shell to completion, causing the formation of intra-polymeric branches and bonds between the metal alkoxides of the primary shell as adsorbed on the surface of the substrate 3 to form a metal oxide coating 5, and acts to strip away any residual precursor solution. As the metal alkoxide precursors are moisture sensitive, the precursors are fully hydrolysed in the presence of water, allowing the reaction to go to completion during rinsing, thereby obviating the requirement for a subsequent high-temperature heat treatment.

Following rinsing, a hydroxylated surface is present on the metal oxide shell, which hydroxylated surface enables further coating, if desired, and thereby a homogeneous increase in the shell thickness. Where thicker films are required, the coating procedure of the coating and rinsing steps is repeated as required.

Following rinsing, the coated substrate 3 is dried by passing a gas flow thereover, in this embodiment the gas flow being at room temperature. In preferred embodiments the gas can be one of air or nitrogen. In another embodiment the coated substrate 3 could be heated at a relatively low temperature, typically at a temperature of less than 100° C.

FIG. 2 illustrates high-resolution TEM images of crystalline TiO₂ nanoparticles coated with an A₂O₃ coating having a thickness of about 1 nm. These particles were broken from a nanocrystalline TiO₂ film coated with an Al₂O₃ overlayer as described hereinabove. The Al₂O₃ overlayer is apparent as the white line around each nanoparticle in the lower resolution image, and as a region of electron density around the edge of the nanocrystal in the higher resolution image.

A particular advantage of the coating method of the present invention is in enabling the fabrication of conformal metal oxide coatings on structured substrates, in particular reticulated or particulate substrates, without the requirement for any high-temperature heat treatment, that is, a heat treatment at a temperature typically above 150° C.

The coating method of the present invention finds particular application in the fabrication of electronic and optoelectronic devices, and in particular photovoltaic devices, such as dye sensitized nanocrystalline solar cells (DSSCs). DSSCs represent an attractive approach to the fabrication of low-cost molecular-based photovoltaics, having the particular advantage of being relatively insensitive to oxygen-induced photodegradation [5, 6].

FIG. 3 schematically represents a DSSC as fabricated in accordance with a preferred embodiment of the present invention.

The DSSC comprises a nanocomposite film 7 which is sandwiched between a pair of electrodes 9, 11, in a preferred embodiment an ITO-PET electrode 9 and a metal sputtered ITO-PET electrode 11.

The nanocomposite film 7 comprises a mesoporous, nanocrystalline film 3, in one embodiment of TiO₂, which is conformally coated with a first coating 5 of a metal oxide, in one embodiment Al₂O₃, as described hereinabove, and a second coating 15 of a sensitizing dye, in one embodiment ruthenium bipyridyl sensitizer dye, and a redox-active electrolyte 17, in one embodiment a polymeric hole conductor, interpenetrated into the pores of the nanocrystalline film 3.

The nanocrystalline film 3 can be fabricated either by sol-gel chemistry, or by high-pressure compression of nanoparticles.

The DSSC of this embodiment is a flexible structure and thus advantageously allows for fabrication using high-throughput, low-cost device fabrication technologies, such as reel-to-reel fabrication technologies.

The present invention will now be described hereinbelow by way of example only with reference to the following non-limiting Examples.

### EXAMPLE I

This Example is directed to the fabrication of a nanocrystalline sandwich solar cell structure comprising an RuL₂(NCS)₂ sensitized Al₂O₃ conformal coating on a TiO₂ film, where L is 4,4′-dicarboxy-2,2′-bipyridyl.

A 0.15 M precursor solution was first prepared of aluminum tri-sec-butoxide in dry iso-propanol.

A preformed mesoporous, nanocrystalline TiO₂ film having a thickness of 8 μm was then coated with the precursor solution by dipping the film in the precursor solution at room temperature for 10 minutes.

The coated film was then rinsed in de-ionized water to form an Al₂O₃ conformal coating.

The Al₂O₃ conformal coating was dried in nitrogen gas, and then sensitized overnight in a 1 mM solution of RuL₂(NCS)₂ in 1:1 acetonitrile/tert-butanol. High-resolution TEM imaging established the thickness of the Al₂O₃ conformal coating at about 1 nm.

FIG. 4 (plot A) illustrates the current-voltage characteristics of the resulting dye-sensitized structure. For reference, FIG. 4 (plot B) illustrates the current-voltage characteristics of an uncoated nanocrystalline TiO₂ film. The determined data was obtained for transparent counter electrodes and an active cell area of 0.8 cm² under AM1.5 simulated sunlight at 100 mWcm⁻², with the insert showing the corresponding dark current data.

As will be noted, the Al₂O₃ conformal coating of the present invention provides a significant improvement in device performance, with the solar-to-electrical power conversion efficiency increasing by 30%.

### EXAMPLE II

This Example is directed to the fabrication of a nanocrystalline sandwich solar cell structure comprising an RuL₂(NCS)₂ sensitized Al₂O₃ conformal coating on a TiO₂ film, where L is 4,4′-dicarboxy-2,2′-bipyridyl.

1 g of TiO₂ (P25) was dispersed in 4 ml of dry ethanol, here by sonication for 30 minutes, to provide a film suspension.

In the preparation of sample films, the suspension was deposited as a film, here doctor bladed, on a 100 Ω-sq ITO-PET sheet (CP Films, USA), dried in air, and the deposited film and supporting sheet were then sandwiched between two polished stainless steel plates and compressed at a pressure of 700 kgcm⁻² to provide a nanoporous TiO₂ film. In this Example, samples were prepared having thicknesses of about 4 μm and about 8 μm.

Ones of the TiO₂ films were then coated with a thin overcoat of Al₂O₃ by dipping in a 7.5 mM solution of Al(BuⁱO)₃ in iso-propanol for 10 minutes. Through investigation, the optimum concentration of the precursor solution was found to be between about 5 and about 7.5 mM Al(BuⁱO)₃.

Each coated TiO₂ film was then rinsed with de-ionized water, here by dipping in a bath of de-ionized water, and subsequently dried.

Each rinsed film was then sensitized with the bis-tetrabutyl ammonium salt of the ruthenium dye Ru(L)₂(NCS)₂.

Transient absorption spectroscopy was employed to interrogate the blocking layer function of Al₂O₃ coating. Utilizing pulsed laser excitation at 610 nm, the yield and decay dynamics of the sensitizer dye cation was monitored by observing the photoinduced absorption signal of this species at 800 nm [7, 8]. Samples were excited at 610 nm with pulses from a nitrogen laser pumped dye laser (<1 ns pulse duration, 0.8 Hz, intensity ˜0.04 mJcm⁻²). The optical density of samples at 610 nm was approximately 0.5. A liquid light guide was used to transmit the excitation pulse to the samples. The probe light was provided by a 100 W tungsten lamp, with wavelength selection being achieved by monochromators upstream and downstream of the samples.

FIG. 5 illustrates the photoinduced absorption of the RuL₂(NCS)₂ cation following optical excitation of the dye adsorbed on an Al₂O₃ coated TiO₂ film (plot A) and an uncoated TiO₂ film (plot B). The decay of the signal is assigned to charge recombination of the dye cation with electrons in trap/conduction band states of the TiO₂ semiconductor.

As the measurements were conducted in the absence of any hole-conductor or redox active electrolyte in the pores of nanoporous structure, the transient decay can be assigned to interfacial charge recombination between injected electrons and the dye cations. It is apparent that the Al₂O₃ coating results in an approximately ten-fold retardation of the recombination, the half times for dye cation decay being 2.7 ms and 34 ms for the uncoated and coated substrates, which is consistent with the blocking layer function of the Al₂O₃ overlayer. It is furthermore apparent from FIG. 5 that the electron injection yield, as monitored by the initial amplitude of the dye cation signal, is essentially unaffected by the blocking overlayer.

Utilizing ones of the nanocomposite structures as fabricated, flexible DSSCs were fabricated as follows.

A NaI/I₂ polymer electrolyte solution comprising 0.3 g poly-epichlorohydrin-co-ethylene oxide, 0.03 g NaI, 0.003 g I₂, 0.15 g ethylene carbonate: propylene carbonate 1:1, in 25 ml acetone was prepared.

The polymer electrolyte solution was then applied to nanocomposite structures to provide for penetration of the polymer electrolyte solution into the pores thereof, and then cast at 60° C. to provide an interpenetrating solid polymer electrolyte.

A platinum coated 100 Ω-sq ITO-PET sheet (CP Films, USA) was then sandwiched to each of the nanocomposite structures to provide DSSCs.

Following fabrication, the resulting devices were characterized without sealing, with the sensitized interlayer and the electrodes being held together by the mechanical strength of the polymer electrolyte.

Devices fabricated by this methodology were found to be highly flexible; with marked flexing of the devices not seemingly degrading device performance.

Photovoltaic performance of the resulting devices was determined for DSSCs incorporating nanocomposite films employing an Al₂O₃ coated TiO₂ film, and, for the purposes of comparison, an uncoated TiO₂ film.

FIG. 6 illustrates the current-voltage characteristics of DSSCs employing an Al₂O₃ coated TiO₂ film (plot A) and an uncoated TiO₂ film (plot B) under dark (inset) and light conditions, where having a film thickness of approximately 8 μm and active cell areas of approximately 1 cm². The data under light conditions was obtained under 10 mWcm⁻² AM1.5 solar illumination.

Corresponding values for the incident photon to current efficiency IPCE (Φ), short circuit current density (J_{sc}), open circuit voltage (V_{oc}), fill factor (FF) and overall efficiency (η) for both Al₂O₃ coated and uncoated TiO₂ films of 4 μm and 8 μm thickness are given in Table 1 hereinbelow. All data presented is average data obtained from a minimum of six devices for each film kind, with all devices fabricated from the same batch. All data, with the exception of IPCE, was determined under 10 mWcm⁻² AM1.5 solar illumination. IPCE data, calculated as the ratio of collected electrons to incident photons, was obtained under monochromatic 520 nm illumination (intensity ˜1.5 mWcm⁻²).

TABLE 1

| | Film | | | | | |
|---|---|---|---|---|---|---|
| | thick- | IPCE | V_{oc}/ | J_{sc}/ | | |
| | ness/μm | Φ/% | mV | mAcm⁻² | FF/% | η/% |
| Al₂O₃—TiO₂ | 8 | 54 ± 2 | 0.68 | 1.30 | 60 | 5.3 ± 0.2 |
| TiO₂ | 8 | 47 ± 2 | 0.67 | 1.18 | 57 | 4.5 ± 0.3 |
| Al₂O₃—TiO₂ | 4 | — | 0.73 | 0.89 | 70 | 4.5 ± 0.2 |
| TiO₂ | 4 | — | 0.69 | 0.80 | 64 | 3.6 ± 0.3 |

It is apparent that, even in the absence of the Al₂O₃ blocking layer, the device efficiencies of the DSSCs having both 4 and 8 μm thick TiO₂ films, these being 3.6 and 4.5% respectively at 1/10 sun, exceeds that reported previously for DSSCs employing a polymer electrolyte. This improvement is currently attributed to an enhancement in the light absorption due to enhanced scattering as provided by the TiO₂ film and the reflective platinum counter electrode.

As will be noted, the provision of the Al₂O₃ overlayer results in a very significant improvement in device performance, with improvements in all cell parameters I_{sc}, V_{oc} and FF, and an overall enhancement in device efficiency of about 20%. At 10 mWcm⁻² solar light illumination, the overall efficiency of the solar cell comprising the 8 μm Al₂O₃—TiO₂ films is 5.3%, the highest value reported to date for flexible solar cells based upon inorganic/organic composite materials.

It is pertinent to note that the exemplified photovoltaic devices were fabricated and studied unsealed under aerobic conditions, and without any optimisation in polymer electrolyte stability. Nevertheless even under the conditions we employ, device stabilities were encouraging with continuous illumination over a period of 80 hours at 20 mWcm⁻² light flux resulting in only a 15% drop in performance.

Finally, it will be understood that the present invention has been described in its preferred embodiments and can be modified in many different ways without departing from the scope of the invention as defined by the appended claims.

Numerous minor modifications of the described coating method can be envisaged to optimize the method for different applications, including minor, low-temperature heat treatments, and different precursors, precursor concentrations and solvents.

### REFERENCES

[1] Tennakone, K., Perera, V. P. S., Kottegoda, I. R. M., Kumara, G. R. R. A., J. Phys. D: Appl. Phys. 1999, 32, pp 374-379.
[2] Tennakone, K., Bandaranayake, P. K. M., Jayaweera, P. V. V., Konno, A., Kumara, G. R. R. A., Physica E 2002, 14, pp 190-196.
[3] Elder, S. H., Cot, F. M., Su, Y., Heald, S. M., Tyryshkin, A. M., Bowman, M. K., Gao, Y., Joly, A. G., Balmer, M. L., Kolwaite, A. C., Magrini, K. A., Blake, D. M., J. Am. Chem. Soc. 2000, 122, pp 5138-5146.
[4] Ichinose, I., Senzu, H., Kunitake, T., Chem. Mater. 1997, 9, pp 1296-1298.
[5] O'Regan, B and Gratzel, M, Nature 1991, 353, p 737.
[6] Hinch, A., Kroon, J. M., Kem, R., Uhlendorf, I., Holzbock, J., Meyer, A., Ferber, J., Progress in Photovoltaics: Research and Applications 2001, 9, p 425.
[7] Tachibana, Y., Moser, J. E., Gratzel, M., Klug, D. R., Durrant., J. R., J. Phys. Chem. 1996, 100 (51), p 20056.
[8] Haque, S. A., Tachibana, R. L., Wilis, R. L., Moser, J. E., Gratzel, M., Klug, D. R., Durrant, J. R., J. Phys. Chem. 2000, 104 (3), p 538.

1-74. (canceled)

75. A low-temperature fabrication method for fabricating a conformal metal oxide coating on a substrate, the method comprising the steps of:
coating a surface of a substrate with a non-hydrolysed precursor solution of one or more moisture-sensitive metal alkoxides in an organic solvent at a temperature of less than 150° C.; and
rinsing the precursor solution coated on the surface of the substrate in water at a temperature of less than 150° C. to hydrolyse precursor solution at the surface of the substrate and thereby form a conformal metal oxide coating on the substrate.

76. The method of claim 75, wherein the one or more moisture-sensitive metal alkoxides comprise M(OR)_{z}, where M is any metal, and OR is an alkoxide group.

77. The method of claim 76, wherein the metal is a metal selected from the group consisting of Al, Ce, Mg, Nb, Si, Sn, Ti, V, Zn and Zr.

78. The method of claim 75, wherein the step of coating a surface of a substrate is performed at room temperature.

79. The method of claim 75, wherein the step of coating a surface of a substrate is performed by dipping the surface of the substrate in the precursor solution, preferably for a period of from about 1 minute to about 1 hour.

80. The method of claim 75, wherein the step of coating a surface of a substrate is performed by spraying the surface of the substrate with the precursor solution.

81. The method of claim 75, wherein the step of coating a surface of a substrate is performed by spin-coating the surface of the substrate with the precursor solution.

82. The method of claim 75, wherein the precursor solution has a concentration of less than about 200 mM, preferably a concentration in the range of from about 1 mM to about 100 mM, and more preferably a concentration in the range of from about 5 mM to about 20 mM.

83. The method of claim 75, wherein the step of rinsing the precursor solution coated on the surface of the substrate is performed at room temperature.

84. The method of claim 75, wherein the step of rinsing the precursor solution coated on the surface of the substrate is performed by dipping the coated surface of the substrate in water.

85. The method of claim 75, further comprising the step of:
drying the rinsed surface of the substrate at a temperature of less than 150° C., preferably at room temperature.

86. The method of claim 85, wherein the step of drying the rinsed surface of the substrate is performed by directing a gas flow thereover.

87. The method of claim 75, wherein the surface of the substrate is a flat surface.

88. The method of claim 75, wherein the surface of the substrate comprises a structured surface.

89. The method of claim 88, wherein the structured surface comprises a nanoporous surface.

90. The method of claim 88, wherein the structured surface comprises a reticulated surface.

91. The method of claim 75, wherein the substrate includes a temperature-sensitive element.

92. The method of claim 91, wherein the temperature-sensitive element is selected from the group consisting of a plastic and a polymer.

93. The method of claim 91, wherein the temperature-sensitive element comprises temperature-sensitive molecules, preferably molecules selected from the group consisting of inorganic, organic and organometallic molecules, polymeric molecules, biomolecules, or biological macromolecules, and more preferably biological macromolecules selected from the group consisting of proteins and nucleic acids.

94. The method of claim 93, wherein the molecules are at the surface of the substrate.

95. The method of claim 94, wherein the coating extends over regions of the surface of the substrate not encompassed by the molecules.

96. The method of claim 94, wherein the coating encapsulates the molecules.

97. The method of claim 75, wherein the substrate comprises particles, preferably dry particles or particles suspended in solution.

98. The method of claim 97, wherein the particles comprise nanoparticles.

99. The method of claim 75, wherein the metal oxide coating has a thickness of from about 0.2 nm to about 10 nm, preferably a thickness of from about 0.2 nm to about 1 nm.

100. A low-temperature fabrication method for fabricating a metal oxide coating on a substrate, the method comprising the steps of:
coating a surface of a substrate with a non-hydrolysed precursor solution of one or more moisture-sensitive metal alkoxides in an organic solvent at a temperature of less than 150° C.; and
hydrolysing precursor solution at the surface of the substrate to form a metal oxide coating at a temperature of less than 150° C.

101. The method of claim 100, wherein the metal oxide coating is a conformal coating.

102. The method of claim 100, wherein the precursor solution has a concentration of less than about 200 mM, preferably a concentration in the range of from about 1 mM to about 100 mM, and more preferably a concentration in the range of from about 5 mM to about 20 mM.

103. The method of claim 100, wherein the step of hydrolysing the precursor solution coated on the surface of the substrate is performed in water.

104. The method of claim 100, wherein the step of hydrolysing the precursor solution coated on the surface of the substrate is performed at room temperature.

105. The method of claim 100, wherein the step of hydrolysing the precursor solution coated on the surface of the substrate is performed by rinsing the coated surface of the substrate.

106. The method of claim 100, further comprising the step of:
drying the hydrolysed surface of the substrate at a temperature of less than 150° C., preferably at room temperature.

107. The method of claim 106, wherein the step of drying the hydrolysed surface of the substrate is performed by directing a gas flow thereover.

108. The method of claim 100, wherein the metal oxide coating has a thickness of from about 0.2 nm to about 10 nm, preferably a thickness of from about 0.2 nm to about 1 nm.

109. A device incorporating a substrate having a metal oxide coating as fabricated by the method of claim 75.

110. The device of claim 109, wherein the device is one of an electronic or optoelectronic device, preferably a photovoltaic device, and more preferably a dye sensitized solar cell.

111. A dye sensitized solar cell device, comprising a nanocomposite film sandwiched between a pair of electrodes, wherein the nanocomposite film comprises a mesoporous, nanocrystalline film conformally coated with a first coating of a metal oxide and a second coating of a sensitizing dye, and a redox-active electrolyte interpenetrated into the pores of the nanocrystalline film.

112. The device of claim 111, wherein the metal oxide coating has a thickness of from about 0.2 nm to about 10 nm, preferably a thickness of from about 0.2 nm to about 1 nm.

113. The device of claim 111, wherein the metal oxide comprises Al₂O₃.

114. The device of claim 111, wherein the nanocomposite film comprises TiO₂.

115. The device of claim 111, wherein the redox-active electrolyte comprises a polymer electrolyte.

116. A non-hydrolysed precursor solution of one or more moisture-sensitive metal alkoxides in an organic solvent.

117. The precursor solution of claim 116, wherein the one or more moisture-sensitive metal alkoxides comprise M(OR)_{z}, where M is any metal, and OR is an alkoxide group.

118. The precursor solution of claim 117, wherein the metal is a metal selected from the group consisting of Al, Ce, Mg, Nb, Si, Sn, Ti, V, Zn and Zr.

119. The precursor solution of claim 116, wherein the precursor solution has a concentration of less than about 200 mM, preferably a concentration in the range of from about 1 mM to about 100 mM, and more preferably a concentration in the range of from about 5 mM to about 20 mM.

120. A method of preparing a non-hydrolysed precursor solution of one or more moisture-sensitive metal alkoxides in an organic solvent, the method comprising the step of mixing one or more moisture-sensitive metal alkoxides in an organic solvent in a controlled environment containing less than about 10 ppm water.

121. The method of claim 120, where performed at room temperature.

122. The method of claim 120, wherein the controlled environment is an inert atmosphere.

123. The method of claim 120, wherein the one or more moisture-sensitive metal alkoxides comprise M(OR)_{z}, where M is any metal, and OR is an alkoxide group.

124. The method of claim 123, wherein the metal is a metal selected from the group consisting of Al, Ce, Mg, Nb, Si, Sn, Ti, V, Zn and Zr.

125. The method of claim 120, wherein the precursor solution has a concentration of less than about 200 mM, preferably a concentration in the range of from about 1 mM to about 100 mM, and more preferably a concentration in the range of from about 5 mM to about 20 mM.
